(19) United States
(12) Patent Application Publication
(10) Pub. No.: US 2012/0050145 A1
(43) Pub. Date: Mar. 1, 2012

(54) METHOD FOR MANUFACTURING A DISPLAY DEVICE, AND DISPLAY DEVICE MANUFACTURED USING SAID METHOD

(75) Inventor: Takuto Yasumatsu, Osaka (JP)

(73) Assignee: SHARP KABUSHIKI KAISHA, Osaka (JP)

(21) Appl. No.: 13/318,045

(22) PCT Filed: Dec. 22, 2009
(86) PCT No.: PCT/JP2009/007104

§ 371 Date: Oct. 28, 2011

(30) Foreign Application Priority Data
Apr. 30, 2009 (JP) 2009-111249

(51) Int. Cl. G09G 3/30; H01L 33/08; B82Y 99/00

(52) U.S. Cl. 345/80; 438/34; 257/E33.053; 977/742

(57) ABSTRACT

A film-shape display substrate (26) is fabricated by forming first TFT elements (4) and an organic EL display element (11) on a film-shape base layer (2). A film-shape driver circuit substrate (27) is fabricated by forming, on a film-shape base layer (40), second TFT elements (41) having a higher mobility than the mobility of the first TFT element (4). Then, in a driver circuit region (21), the display substrate (26) and the driver circuit substrate (27) are bonded together via an adhesive conductive member (28), and the first TFT element (4) so that the second TFT elements (41) are electrically connected.

### TECHNICAL FIELD

The present invention relates to a method of manufacturing a display device, and a display device manufactured by the method thereof.

### BACKGROUND ART

In recent years, in the field of displays, a thin display device including a plastic substrate or the like that has greater advantages than a glass substrate in terms of flexibility, impact resistance, and lightness has been receiving a great deal of attention, and there is a possibility that a new display, which has been unachievable by a display with a glass substrate, may be created.

In forming a thin film device, such as a thin display device, a technique of forming a thin film device on a supporting substrate prepared separately, and transferring the device to a desired substrate has been proposed.

More specifically, after forming a separation layer (light absorption layer) on a glass substrate first, a thin film device layer, which is a layer to be transferred, is formed. This thin film device layer has TFT (Thin Film Transistor) elements for a display device, which include a polysilicon layer. Next, the thin film device layer is bonded (adhered) onto a transfer body made of a synthetic resin via an adhesive layer. Next, after irradiating the glass substrate with laser light from the back surface, the glass substrate is removed from the separation layer. Then, by removing the remaining separation layer, the thin film device layer is transferred to the transfer body (See Patent Document 1, for example).

### RELATED ART DOCUMENTS

### Patent Documents

Patent Document 1: Japanese Patent Application Laid-Open Publication No. H10-125931

### SUMMARY OF THE INVENTION

### Problems to be Solved by the Invention

However, in the transfer technique described above, it is necessary to bond a thin film device (TFT element) to the entire surface of a transfer body made of a synthetic resin, and therefore, it is necessary to use a transfer body made of a rigid synthetic resin, resulting in a problem of reducing flexibility. Additionally, the configuration of transferring a thin film device layer to a transfer body requires two transfer processes (temporary transfer and main transfer to a flexible substrate), causing a problem of reducing the yield of the display device. Further, the configuration of transferring a thin film device layer to a transfer body has another problem that, because it is necessary to apply mechanical stress, it is difficult to fabricate a display device having a large screen in particular.

The present invention was made in view of the above-mentioned problems and it is an object of the present invention to provide a method of manufacturing a display device that has a higher flexibility and a high yield, and that can be provided with a large screen, and a display device manufactured by such a method.

### Means for Solving the Problems

To achieve the above mentioned object, a method of manufacturing a display device of the present invention is a method for manufacturing a display device including a display region having pixels, and a driver circuit region disposed around the display region, and includes at least: a first step of fabricating a film-shape display substrate by forming a first TFT element that is a switching element of the pixel and a display element on a first substrate; a second step of fabricating a film-shape driver circuit substrate by forming, on a second substrate, a second TFT element that is an active element of a driver circuit and that has a higher mobility than a mobility of the first TFT element; and a third step of bonding the display substrate and the driver circuit substrate via an adhesive conductive member to electrically connect the first TFT element and the second TFT element in a driver circuit region.

According to such a configuration, because of the configuration of bonding the film-shape display substrate and the film-shape driver circuit substrate together, the entire display device can be formed of films. Therefore, a display device with a superior flexibility can be provided.

Also, because of the configuration of bonding the display substrate and the driver circuit substrate via the conductive member, the yield of a display device can be improved as compared with a case of transferring a TFT element to a transfer body.

Further, the mobility of the first TFT element formed on the display substrate is smaller than the mobility of the second TFT element. Therefore, a display device having a large screen (that is, a large display region) can be provided. Also, the mobility of the second TFT element formed on the driver circuit substrate is greater than the mobility of the first TFT element. Therefore, a display device having a driver circuit capable of rapid response can be provided.

In the method of manufacturing a display device according to the present invention, the conductive member may be a conductive adhesive.

According to such a configuration, a conductive adhesive is used as the conductive member. Therefore, when the display substrate and the driver circuit substrate are bonded together, the first TFT element and the second TFT element can be electrically connected reliably with ease.

In the method of manufacturing a display device according to the present invention, the conductive member may be a conductive paste.

According to such a configuration, a conductive paste is used as the conductive member. Therefore, when the display substrate and the driver circuit substrate are bonded together, the first TFT element and the second TFT element can be electrically connected reliably with ease.

In the method of manufacturing a display device according to the present invention, the first substrate and the second substrate may be formed of the same material.

According to such a configuration, thermal expansion coefficients of the first substrate and the second substrate can be set to the same value, and therefore, a distortion in bonding the display substrate and the driver circuit substrate can be reduced.

The method of manufacturing a display device according to the present invention may further include a step of covering, with a laminate layer, a bonded body obtained by bonding the display substrate and the driver circuit substrate after the above-mentioned third step.

According to such a configuration, a bonded body obtained by bonding the display substrate and the driver circuit substrate is covered with the laminate layer. Therefore, damages to a display device caused by dirt, dust, or the like can be effectively prevented.

In the method of manufacturing a display device according to the present invention, the laminate layer may be formed of a polyparaxylene resin.

According to such a configuration, the laminate layer is formed of a polyparaxylene resin. Therefore, the insulation protection for a display device can be provided.

In the method of manufacturing a display device according to the present invention, the first TFT element may use one material selected from a group constituted of amorphous silicon, an organic semiconductor, and a carbon nanotube as a channel thereof, and the second TFT element may use polysilicon as a channel thereof.

According to such a configuration, generally available materials can be used to form the first TFT elements that can provide a large screen, and to form a second TFT element capable of rapid response.

Also, the method of manufacturing a display device according to the present invention has an excellent characteristic of being able to provide a display device with higher flexibility and yield, as well as a large display region. Therefore, the method of manufacturing a display device according to the present invention can be suitably used for a method of manufacturing a display device using an organic EL display element as the display element thereof.

### EFFECTS OF THE INVENTION

According to the present invention, a display device having higher flexibility and yield as well as a large screen can be provided.

### DETAILED DESCRIPTION OF EMBODIMENTS

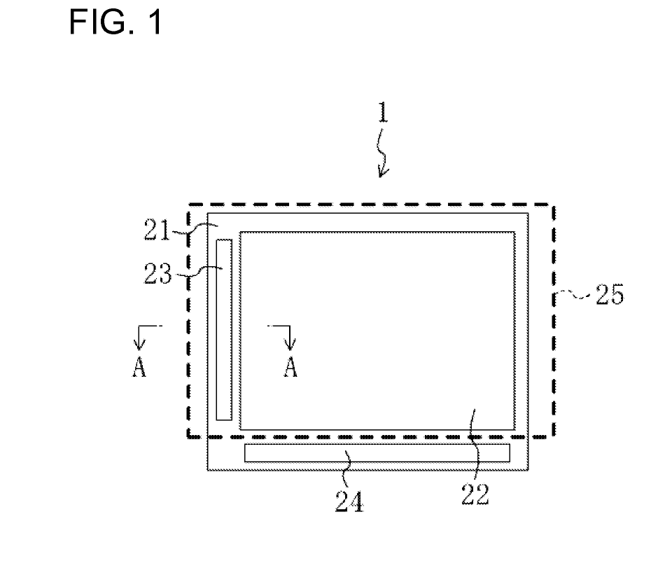

FIG. 1 is a plan view of an organic EL display device according to an embodiment of the present invention.

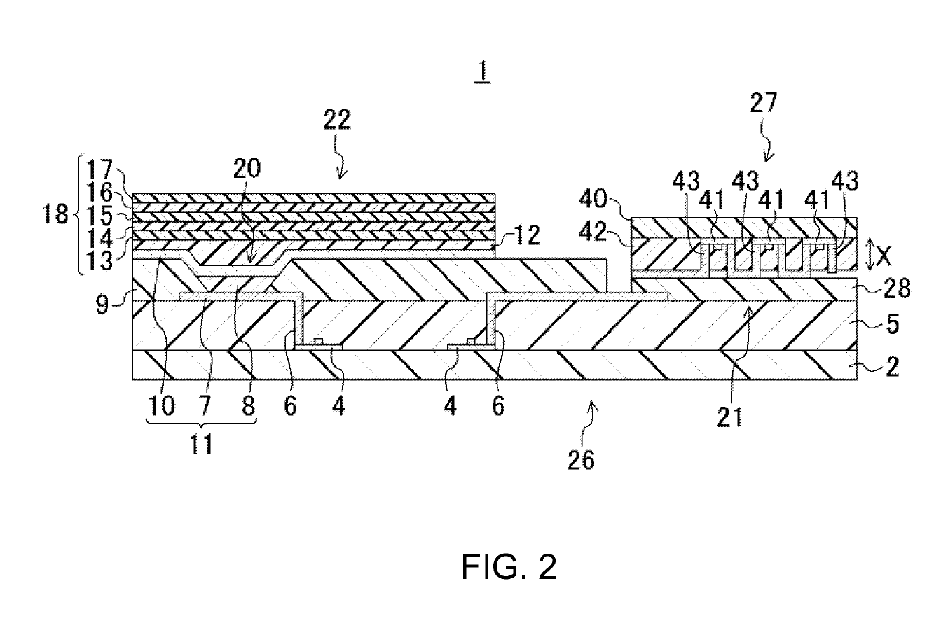

FIG. 2 is a cross-sectional view along the line A-A in FIG. 1.

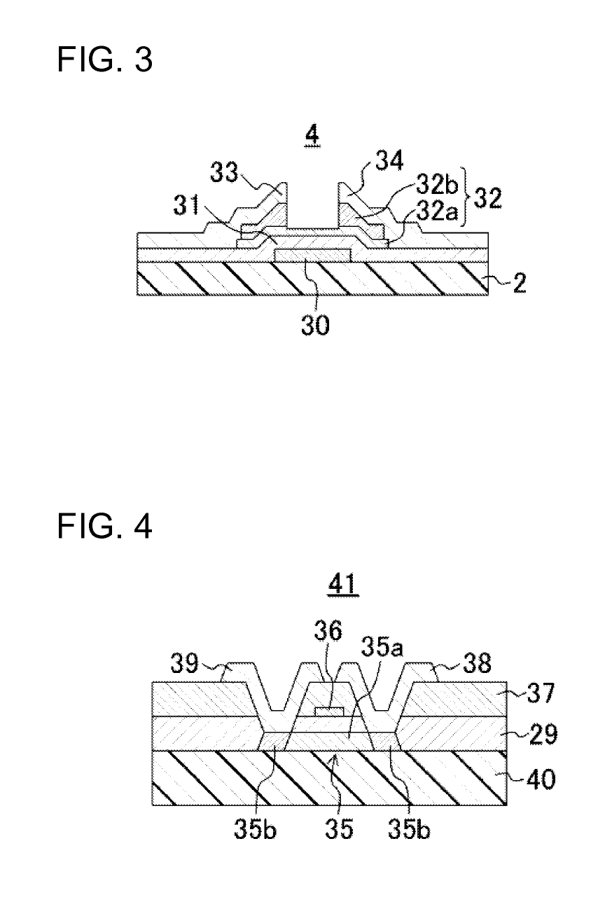

FIG. 3 is a cross-sectional view illustrating a first TFT element in an organic EL display device according to an embodiment of the present invention.

FIG. 4 is a cross-sectional view illustrating a second TFT element in an organic EL display device according to an embodiment of the present invention.

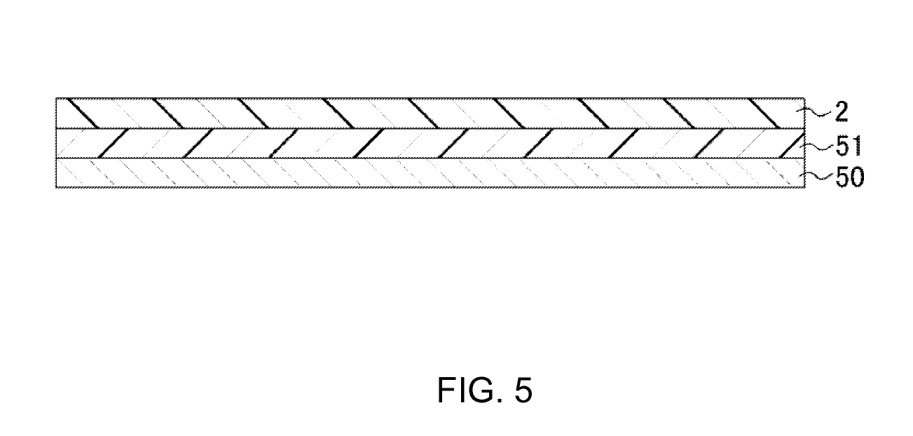

FIG. 5 is a cross-sectional view illustrating a method of manufacturing a display substrate in an organic EL display device according to an embodiment of the present invention.

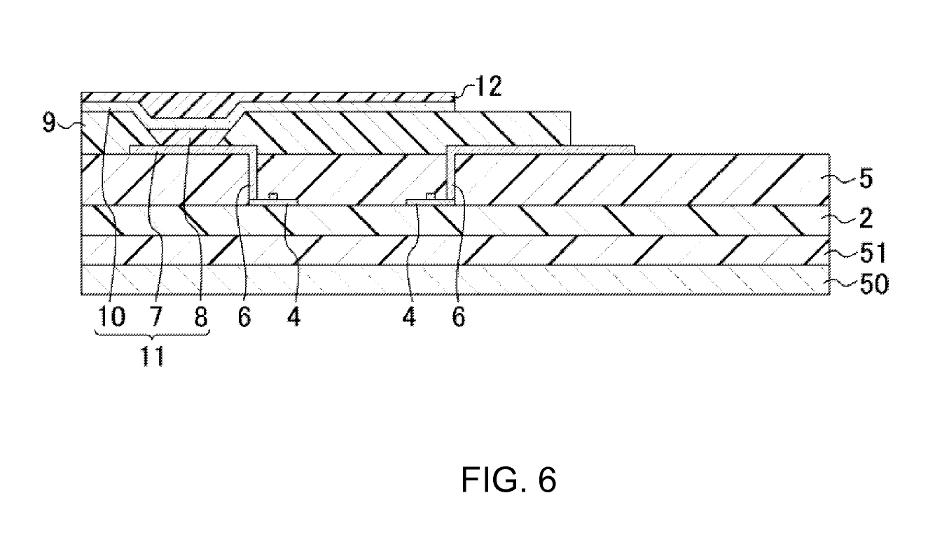

FIG. 6 is a cross-sectional view illustrating a method of manufacturing a display substrate in an organic EL display device according to an embodiment of the present invention.

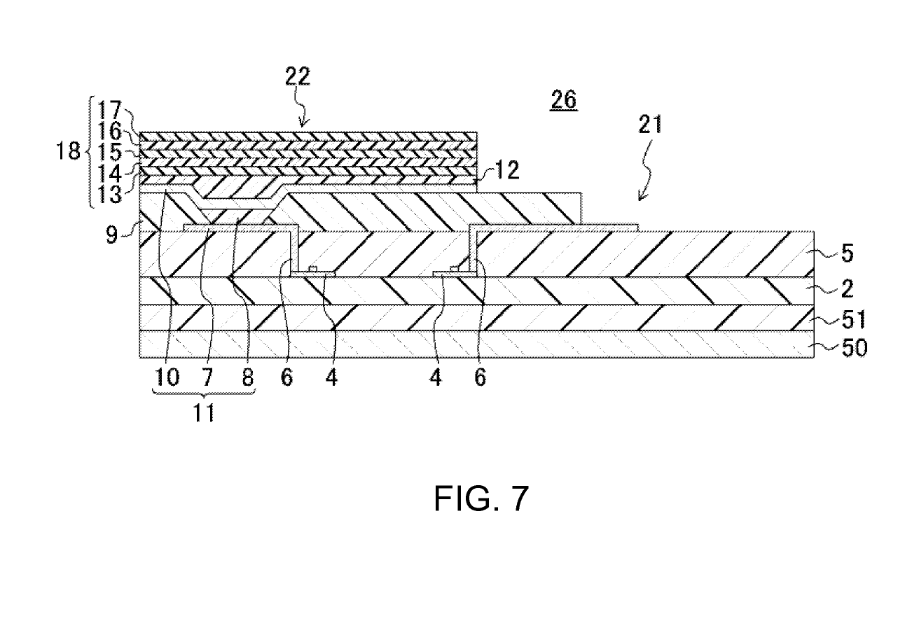

FIG. 7 is a cross-sectional view illustrating a method of manufacturing a display substrate in an organic EL display device according to an embodiment of the present invention.

FIG. 8 is a cross-sectional view illustrating a method of manufacturing a driver circuit substrate in an organic EL display device according to an embodiment of the present invention.

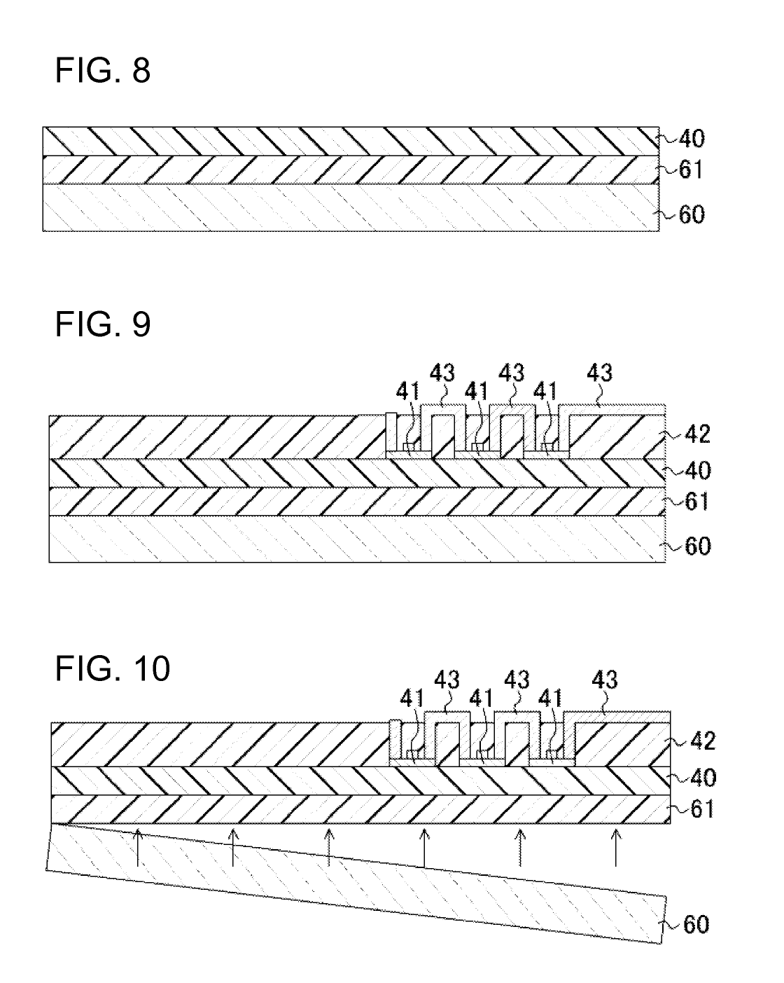

FIG. 9 is a cross-sectional view illustrating a method of manufacturing a driver circuit substrate in an organic EL display device according to an embodiment of the present invention.

FIG. 10 is a cross-sectional view illustrating a method of manufacturing a driver circuit substrate in an organic EL display device according to an embodiment of the present invention.

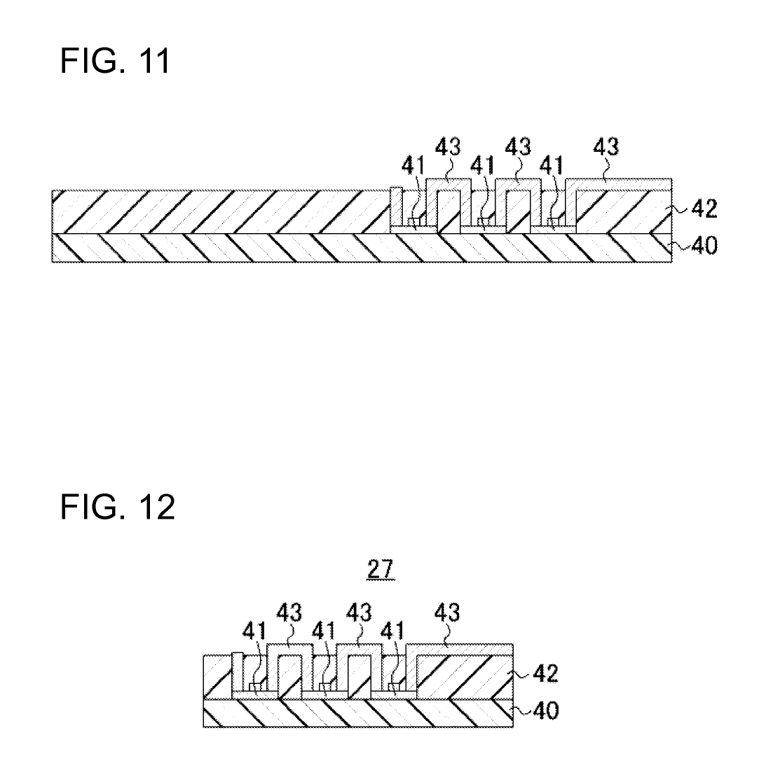

FIG. 11 is a cross-sectional view illustrating a method of manufacturing a driver circuit substrate in an organic EL display device according to an embodiment of the present invention.

FIG. 12 is a cross-sectional view illustrating a method of manufacturing a driver circuit substrate in an organic EL display device according to an embodiment of the present invention.

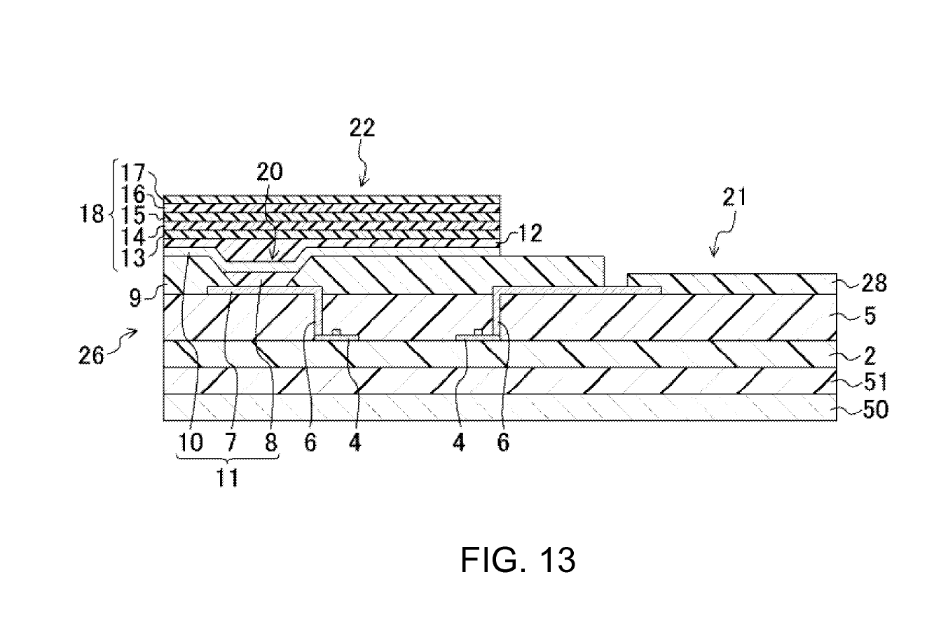

FIG. 13 is a cross-sectional view illustrating a substrate bonding step of an organic EL display device according to an embodiment of the present invention.

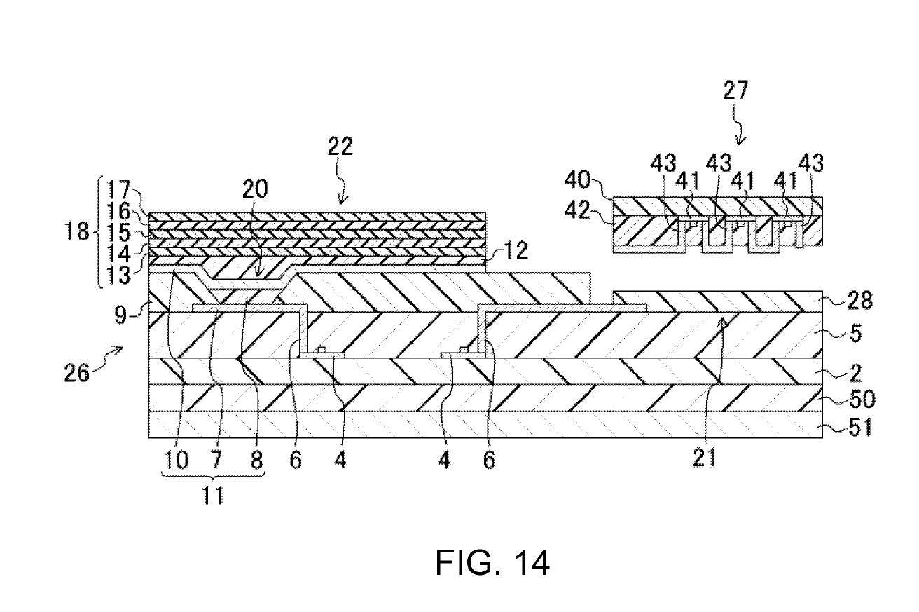

FIG. 14 is a cross-sectional view illustrating a substrate bonding step of an organic EL display device according to an embodiment of the present invention.

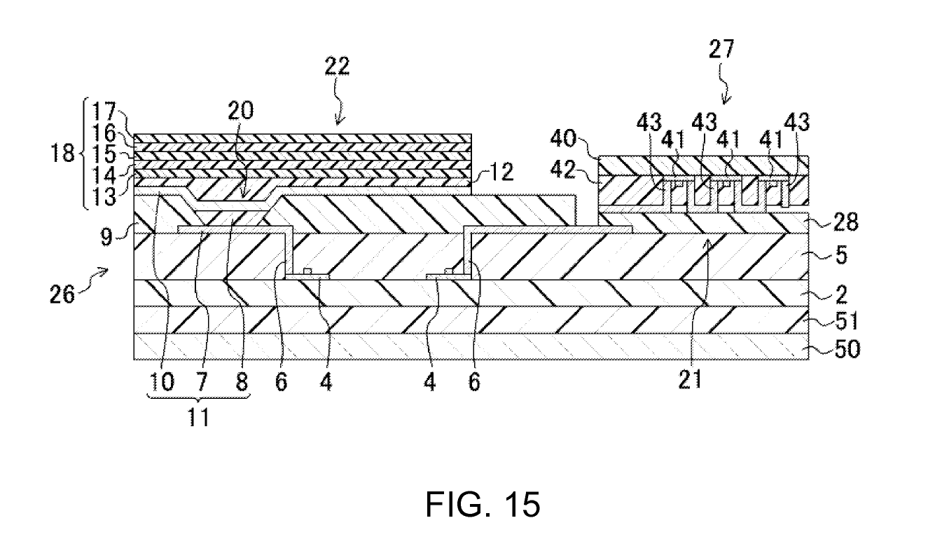

FIG. 15 is a cross-sectional view illustrating a substrate bonding step of an organic EL display device according to an embodiment of the present invention.

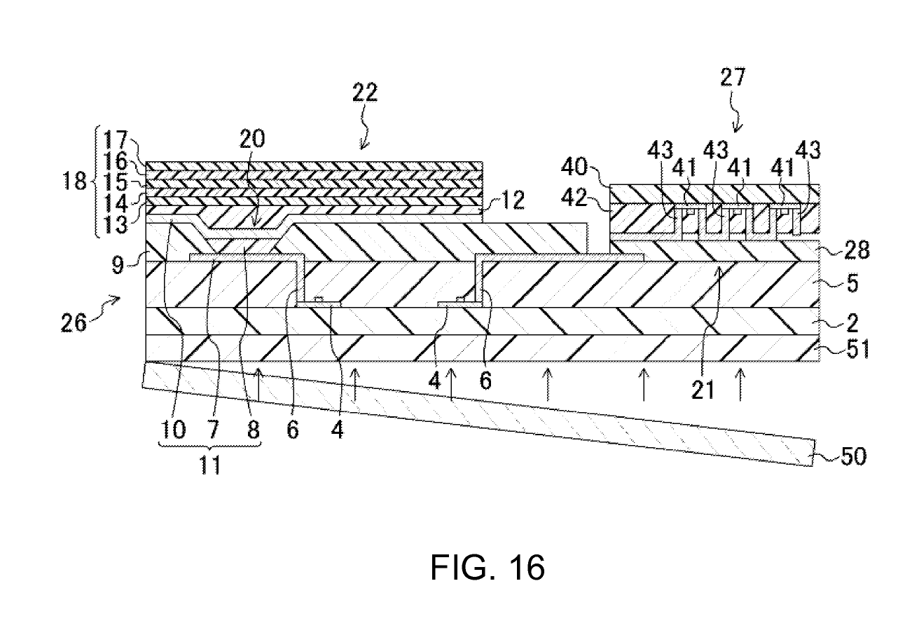

FIG. 16 is a cross-sectional view illustrating a substrate bonding step of an organic EL display device according to an embodiment of the present invention.

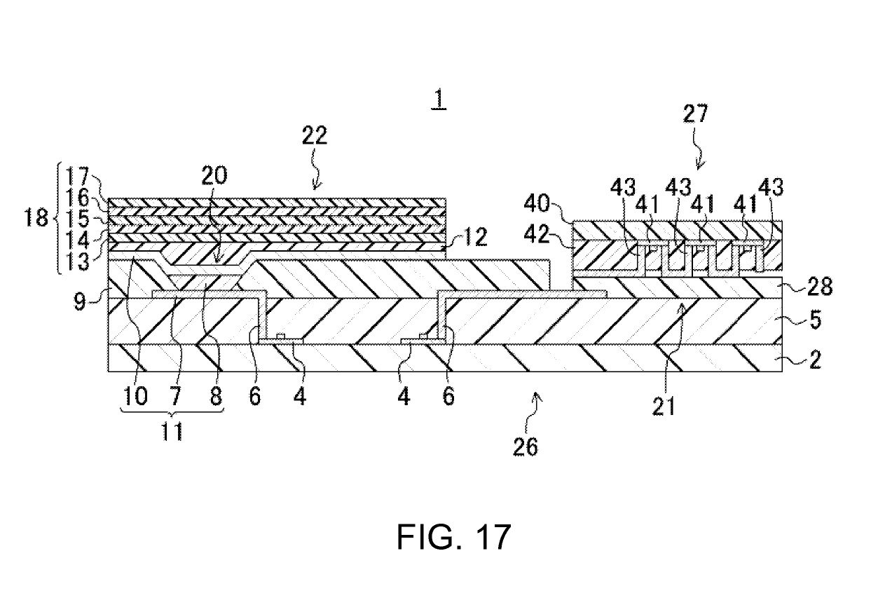

FIG. 17 is a cross-sectional view illustrating a substrate bonding step of an organic EL display device according to an embodiment of the present invention.

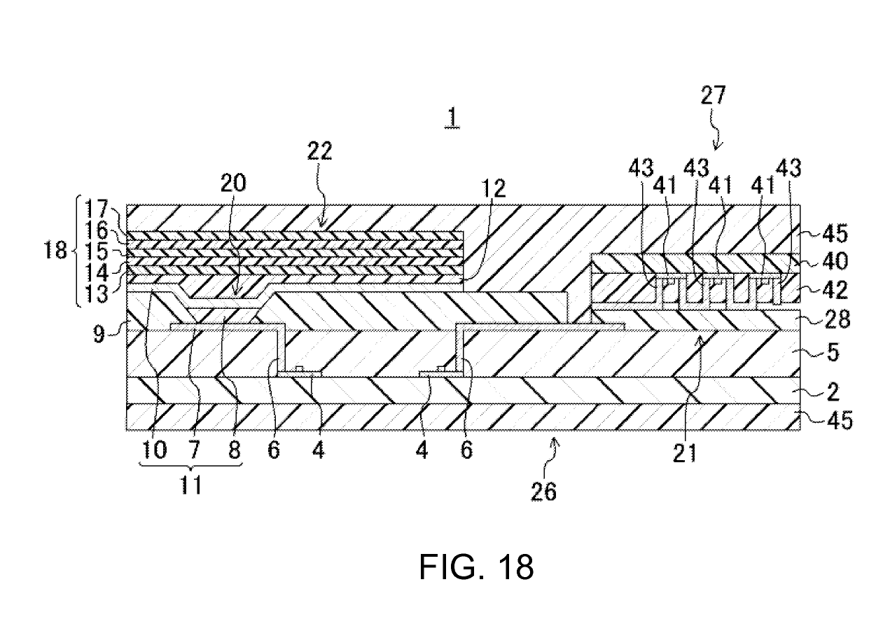

FIG. 18 is a cross-sectional view illustrating a modification example of an organic EL display device according to an embodiment of the present invention.

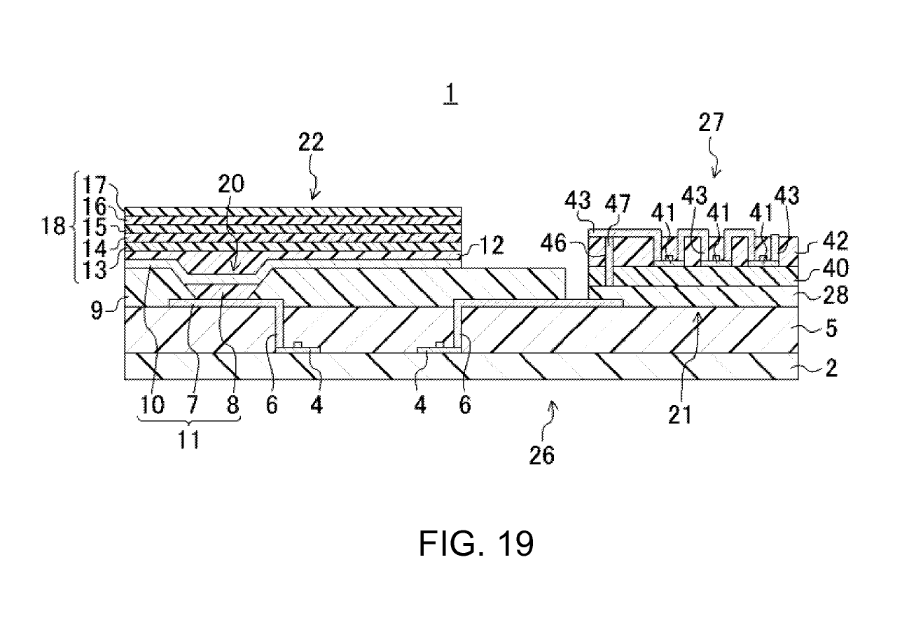

FIG. 19 is a cross-sectional view illustrating a modification example of an organic EL display device according to an embodiment of the present invention.

### DETAILED DESCRIPTION OF EMBODIMENTS

Hereinafter, display devices according to embodiments of the present invention will be explained in detail with reference to figures, but the present invention is not limited to such. Also, in the embodiments, explanations will be made using an organic EL display device as an example of the display device.

FIG. 1 is a plan view of an organic EL display device according to an embodiment of the present invention. FIG. 2 is a cross-sectional view along the line A-A in FIG. 1. FIG. 3 is a cross-sectional view illustrating a first TFT element in an organic EL display device according to an embodiment of the present invention. FIG. 4 is a cross-sectional view illustrating a second TFT element in an organic EL display device according to an embodiment of the present invention.

As shown in FIG. 1, an organic EL display device 1 includes a display region 22 constituted by a plurality of pixels and the like, and a driver circuit region 21 disposed around the display region 22, for example. In the driver circuit region 21, a gate driver 23 for driving gate lines of the display region 22, and a source driver 24 for driving source lines of the display region 22 are disposed. Also, in the organic EL display device 1, because base layers are formed to be film-shape using a polyparaxylene resin or the like, as described below, a large region indicated by a dotted line frame 25 in FIG. 1 has an excellent flexibility, for example. Also, the flexible region is not limited to the region indicated by the dotted line frame 25 in FIG. 1, but can be formed in a desired area by adjusting a configuration of the film substrates and the like.

Also, as shown in FIG. 2, the organic EL display device 1 includes a display substrate 26, and a driver circuit substrate 27 disposed over the display substrate 26. The thickness of the display substrate 26 is 15 to 30 μm, and the display substrate 26 is a film-shape substrate with a high flexibility. The thickness of the driver circuit substrate 27 is 7 to 10 μm, and the display substrate 27 is a film-shape substrate with a high flexibility.

The display substrate 26 of the organic EL display device 1 includes a base layer 2, which is a film-shape first substrate constituted of a colorless, transparent resin film vapor-deposited at room temperature. For the colorless, transparent resin film constituting the base layer 2, an organic material, such as a poly-para-xylene resin, an acrylic resin, or the like can be used, for example. The thickness of the base layer 2 can be set to 3 to 10 μm, for example.

On the base layer 2, a display element layer including first TFT elements 4 and the like is formed. This display element layer is constituted by the first TFT elements 4 formed on the base layer 2, an interlayer insulating film 5 made of an SiO₂ film, an SiN film, or the like, and disposed to cover the first TFT elements 4, and metal wiring lines 6 that are electrically connected to the first TFT elements 4, penetrating through the interlayer insulating film 5. The metal wiring line 6 is further extended on the interlayer insulating film 5 to constitute a first electrode 7 of an organic EL display element 11. Also, an insulating film (or a bank) 9 for dividing respective pixels (regions) 20 is formed on the interlayer insulating film 5. For a material to form this insulating film 9, an insulating resin material, such as a photosensitive polyimide resin, an acrylic resin, a methallyl resin, or a novolac resin, can be used, for example. The thickness of the interlayer insulating film 5 can be set to 0.5 to 1 μm, for example. Also, the thickness of the insulating film 9 can be set to 2 to 4 μm, for example.

The organic EL display device 1 is a bottom emission type, in which emitted light is extracted from the first electrode 7 side. Therefore, from a perspective of improving the extraction efficiency of the emitted light, it is preferable to constitute the first electrode 7 of a thin film made of a material having a high work function and a high transmittance, such as ITO or SnO₂, for example.

An organic EL layer 8 is formed on the first electrode 7. The organic EL layer 8 is constituted by a hole transporting layer and a light emitting layer. There is no limitation on the hole transporting layer as long as it has a high hole injection efficiency. As a material of the hole transporting layer, an organic material or the like, such as a triphenylamine derivative, a poly-para-phenylen vinylene (PPV) derivative, or a polyfluorene derivative, can be used, for example.

The light emitting layer is not particularly limited to, but can be made of 8-hydroxyquinolinol derivative, thiazole derivative, benzoxazole derivative, or the like, for example. Alternatively, combining two or more kinds of such materials, or combining with an additive, such as a dopant material, is also possible.

Here, the organic EL layer 8 is configured to have a two-layer structure constituted of the hole transporting layer and the light emitting layer, but is not limited to such a configuration. That is, the organic EL layer 8 may have a single layer structure constituted of a light emitting layer only. Alternatively, the organic EL layer 8 may be constituted of a light emitting layer, and one, two, or more layers of a hole transporting layer, a hole injecting layer, an electron injecting layer, and an electron transporting layer.

Also, on the organic EL layer 8 and the insulating film 9, a second electrode 10 is formed. The second electrode 10 has a function of injecting electrons to the organic EL layer 8. The second electrode 10 can be constituted of a thin film made of Mg, Li, Ca, Ag, Al, In, Ce, Cu, or the like, for example, but is not limited to such.

An organic EL display element 11 therefore is constituted by the first electrode 7, the organic EL layer 8 that is formed on the first electrode 7 and that has a light emitting layer, and the second electrode 10 formed on the organic EL layer 8.

Also, in the organic EL display device 1, the first electrode 7 has a function of injecting holes to the organic EL layer 8, and the second electrode 10 has a function of injecting electrons to the organic EL layer 8. The organic EL layer 8 is designed to emit light as a result of holes and electrons injected from the first electrode 7 and the second electrode 10, respectively, recombined in the organic EL layer 8. Additionally, the base layer 2 and the first electrode 7 are configured to be light transmissive, and the second electrode 10 is configured to be light reflective, and therefore, emitted light is designed to transmit the first electrode 7 and the base layer 2 so as to be extracted from the organic EL layer 8 (bottom emission type).

Also, on the second electrode 10, a planarizing film 12 made of an acrylic resin, a poly-para-xylene resin, or the like is formed. The thickness of the planarizing film 12 can be set to 3 to 8 μm, for example.

On the planarizing film 12, a sealing film 18 constituted by a laminate made of resin films 13, 15, and 17, an inorganic film 14, and a metal oxide film 16 is formed. The resin films 13, 15, and 17 may be formed by using the same resin material as that of the planarizing film 12, or may be formed by using other resin materials. The inorganic film 14 and the metal oxide film 16 are formed by using SiNx, SiO₂, Al₂O₃, or the like, for example.

The sealing film 18 is not required to have resin films and inorganic films laminated in the multiple layers as described above, and may have a single layer of each film formed therein. Further, the sealing film 18 may be constituted by using a metal thin film. Also, the thickness of the sealing film 18 can be set to 1 to 5 μm, for example.

Also, the first TFT element 4 is a TFT using amorphous silicon, and the amorphous silicon is used as a channel thereof. Because of the amorphous nature thereof, the carrier mobility of electrons and the like of the first TFT element is lower than that of a TFT element using polysilicon, but the first TFT element 4 can provide a display device having a large screen (that is, a large display region).

As shown in FIG. 3, the first TFT 4 includes a gate electrode 30 and a gate insulating film 31 disposed so as to cover the gate electrode 30. Also, the first TFT 4 includes an island-shape semiconductor layer 32 disposed on the gate insulating film 31 in a position overlapping the gate electrode 30, and a source electrode 33 and a drain electrode 34 that are disposed so as to face each other on the semiconductor layer 32. Also, as shown in FIG. 3, the semiconductor layer 32 includes an intrinsic amorphous silicon layer 32a in a lower layer, and n⁺ amorphous silicon layers 32b with phosphorus doped therein in the upper layer. The intrinsic amorphous silicon layer 32a exposed from the source electrode 33 and the drain electrode 34 constitutes a channel region.

As described above, the organic EL display device 1 includes the display substrate 26 having the base layer 2, which is a film-shape first substrate, on which a first TFT element 4, which is a switching element for the pixel 20, and the organic EL display element 11 are formed.

Also, in this embodiment, the driver circuit substrate 27 of the organic EL display device 1 constitutes the gate driver 23, and includes a base layer 40, which is a film-shape second substrate made of a colorless, transparent resin film vapor-deposited at room temperature. The colorless, transparent resin film constituting the base layer 40 is formed of the same material as that of the above-mentioned base layer 2 for which an organic material, such as a polyparaxylene resin, an acrylic resin, or the like can be used, for example. The thickness of the base layer 40 can be set to 3 to 10 μm, for example.

On the base layer 40, second TFT elements 41, which are active elements of a driver circuit (that is, the gate driver 23), and having a higher mobility than the mobility of the first TFT element 4 are formed. Also, on the base layer 40, an interlayer insulating film 42 made of an SiO₂ film, an SiN film, or the like is disposed so as to cover the TFT elements 41. The thickness of this interlayer insulating film 42 can be set to 0.5 to 1 μm, for example. Additionally, on the driver circuit substrate 27, metal wiring lines 43 that are penetrating the interlayer insulating film 42, and are electrically connected to the second TFT elements 41 are disposed.

The second TFT elements 41 are TFTs including polysilicon, and the polysilicon is used as the channels thereof. Such second TFT elements 41 have a higher carrier mobility of electrons and the like, as compared with the above-described first TFT 4 element including amorphous silicon, and are therefore capable of rapid response as active elements of the driver circuit.

As shown in FIG. 4, the second TFT 41 includes a semiconductor layer 35 formed in an island-shape, and a gate insulating film 29 disposed on the semiconductor layer 35. Also, the second TFT 41 includes a gate electrode 36 disposed on the gate insulating film 29, an interlayer insulating film 37 disposed so as to cover the gate electrode 36, and a source electrode 39 and a drain electrode 38 that are disposed so as to face each other on the semiconductor layer 35. Also, as shown in FIG. 4, the semiconductor layer 35 includes an intrinsic polysilicon layer 35a and n⁺ polysilicon layers 35b with phosphorus doped therein, disposed so as to face each other having the intrinsic polysilicon layer 35a therebetween. The intrinsic polysilicon layer 35a constitutes a channel region.

Also, as shown in FIG. 2, the organic EL display device 1 according to this embodiment has a configuration, in which in the driver circuit region 21, the display substrate 26 and the driver circuit substrate 27 are bonded together via an adhesive conductive member 28, and the first TFT element 4 and the second TFT elements 41 are electrically connected.

More specifically, as shown in FIG. 2, the metal wiring line 6 electrically connected to the first TFT element 4, and the metal wiring lines 43 electrically connected to the second TFT elements 41 are adhered to the conductive member 28, and the conductive member 28 and the two metal wiring lines 6 and 43 are electrically connected. The first TFT element 4 and the second TFT elements 41 are therefore electrically connected through these conductive member 28 and two metal wiring lines 6 and 43.

There is no specific limitation on the conductive member 28 as long as it is conductive, and has adhesive properties that can adhesively secure the display substrate 26 and the driver circuit substrate 27. A film-shape conductive adhesive, a conductive paste, or the like can be used for the conductive member 28, for example.

For the conductive adhesive, a material including conductive particles can be used. A conductive adhesive that is mainly made of an insulating thermosetting resin and that has conductive particles dispersed in the resin can be used, for example.

For the thermosetting resin, an epoxy resin, a polyimide resin, a polyurethane resin, or the like can be used, for example. It is, however, preferable to use an epoxy resin as the thermosetting resin from a perspective of improving the adhesive property and the film formability of the conductive adhesive. Also, for the conductive particles, metal particles of copper, silver, gold, nickel, or the like can be used, for example. Here, the conductive adhesive needs to be mainly made of at least one kind of the above-mentioned thermosetting resins, and needs to use at least one kind of the above-mentioned metal particles.

Also, an anisotropic conductive adhesive including conductive particles can be used as the conductive adhesive. More specifically, as the anisotropic conductive adhesive, an adhesive that is mainly made of the above-mentioned insulating thermosetting resin, such as an epoxy resin, and that has conductive particles made of the above-mentioned metal particles dispersed in the resin can be used, for example. By using an anisotropic conductive adhesive as the conductive member 28, the conductive member 28 that has conductivity in the thickness direction (the direction indicated with an arrow X in FIG. 2) of the anisotropic conductive adhesive (that is, the conductive member 28) so as to fix two metal wiring lines 6 and 43 to face each other and to electrically connects the metal wiring lines 6 and 43 and that has insulating properties in the other directions can be realized. For this anisotropic conductive adhesive, a film-shape anisotropic conductive film can be used, for example.

As the conductive paste, a paste type of the above-mentioned conductive adhesives can be used. A thermosetting conductive paste mainly made of conductive particles, a binder resin, and a solvent can be used, for example. Here, as the conductive particles, metal particles of copper, silver, gold, nickel, or the like can be used, for example. Also, as the binder resin, epoxy resin, polyimide resin, polyurethane resin, or the like can be used, for example. Further, as the solvent, butyl acetate, butyl carbitol acetate, or the like can be used, for example. The conductive member 28 is formed by applying a conductive paste to the surface of the display substrate 26 with a screen printing method, an intaglio printing method, or the like, and by curing the binder resin by performing heat treatment, for example. Here, a configuration of including a curing agent and the like is also possible, if necessary. When an epoxy resin is used as the binder resin, an amine compound or an imidazole compound can be used as the curing agent, for example.

Hereinafter, a method of manufacturing the organic EL display device 1 according to an embodiment of the present invention will be explained. The manufacturing method described below is illustrative only, and the organic EL display device 1 according to the present invention is not limited to a device manufactured by the method described below. Also, a manufacturing method according to this embodiment includes a display substrate fabrication step, a driver circuit substrate fabrication step, and a substrate bonding step.

(Display Substrate Fabrication Step)

First, as shown in FIG. 5, a glass substrate 50 in the thickness of about 0.7 mm, for example, is prepared as a supporting substrate.

Next, as shown in FIG. 5, on the glass substrate 50, a sacrificial film 51 made of a resin material with a heat resistant temperature (or glass transition temperature) of 400° C. or higher, and a thermal expansion coefficient of 10 ppm/° C. or lower, for example, is formed in the thickness of about 0.1 to 1 μm, for example. As a resin material of the sacrificial film 51 meeting such conditions, a polyimide resin can be used, for example. This sacrificial film 51 is for removing the glass substrate 50 effectively.

Next, in case of a transmissive display element, a film-shape base layer 2 constituted of a transparent resin film is formed on the sacrificial film 51 in the thickness of about 5 μm, for example. As a resin material forming the base layer 2, a polyimide resin, a fluorene-type epoxy resin, or a fluorine resin can be used. Also, the base layer 2 is formed by applying a resin onto the surface of the sacrificial film 51. Here, in case of a reflective display element, or in case of a top emission self-light emitting display element, a sacrificial film may be omitted by forming the base layer 2 using the same resin material as the resin material used to form the sacrificial film 51.

Thereafter, as shown in FIG. 6, on the base layer 2, first TFT elements 4, which are switching elements for the pixel 20, are formed by forming a metal film, a semiconductor film, and the like, and performing patterning and the like.

Next, on the base layer 2 having the first TFT elements 4 formed thereon, an interlayer insulating film 5 is formed in the thickness of about 1 to 2 μm, using an SiO₂ film, an SiN film, or the like, for example.

Then, contact holes running from the surface of the interlayer insulating film 5 to the first TFT elements 4 are formed, and metal wiring lines 6 electrically connected to the first TFT elements 4 are formed by a transparent conductive material such as ITO. Further, a first electrode 7 having a thickness of about 150 nm, for example, is formed by patterning or the like.

Next, on the interlayer insulating film 5, an insulating film 9 having a thickness of about 3 μm, for example, is formed, and then, a portion corresponding to the first electrode 7 is removed by etching.

Then, an organic EL layer 8 is disposed by forming a hole transporting layer and a light emitting layer on the first electrode 7. For the hole transporting layer, first, a coating compound of a hole transporting material, obtained by dissolving or dispersing an organic polymer material, which is a hole transporting material, in a solvent, is supplied to the exposed first electrode 7 by an inkjet method or the like, for example. After that, by performing a baking treatment, the hole transporting layer is formed. Next, for the light emitting layer, a coating compound of an organic light emitting material, obtained by dissolving or dispersing an organic polymer material, which is a light emitting material, in a solvent, is supplied by an inkjet method or the like, for example, so as to cover the hole transporting layer. After that, by performing a baking treatment, the light emitting layer is formed.

Thereafter, on the insulating film 9 and the organic EL layer 8, a second electrode 10 is formed by sputtering or the like, using Mg, Li, Ca, Ag, Al, In, Ce, Cu, or the like. The thickness of the second electrode 10 is set to about 150 nm, for example. In this manner, an organic EL element 11 including the first electrode 7, the organic EL layer 8 that is formed on the first electrode 7 and that has a light emitting layer, and the second electrode 10 formed on the organic EL layer 8 is formed.

Next, on the second electrode 10, a planarizing film 12 is formed by forming a TEOS film, an SiN film, or the like, and polishing the surface by Chemical Mechanical Polishing (CMP) or the like.

Next, as shown in FIG. 7, a sealing film 18 is formed by forming a resin film 13, an inorganic film 14, a resin film 15, a metal oxide film 16, and a resin film 17 in this order on the planarizing film 12. The resin films 13, 15, and 17 are formed to be about 5 μm thick, respectively, using a polyparaxylene resin or the like, for example. Also, the inorganic film 14 and the metal oxide film 16 are formed to be about 500 nm thick, respectively, using SiNx, SiO₂, Al₂O₃, or the like, for example.

In a manner described above, the display substrate 26 including the glass substrate 50 and the sacrificial film 51 is fabricated.

(Driver Circuit Substrate Fabrication Step)

First, as shown in FIG. 8, a glass substrate 60 in the thickness of about 0.7 mm, for example, is prepared as a supporting substrate.

Next, as shown in FIG. 8, on the glass substrate 60, a sacrificial film 61 made of a resin material with a heat resistant temperature (or glass transition temperature) of 400° C. or higher, and a thermal expansion coefficient of 10 ppm/° C. or lower, for example, is formed in the thickness of about 0.1 to 1 μm, for example. As a resin material of the sacrificial film 61, the same material as that of the above-mentioned sacrificial film 51 can be used. This sacrificial film 61 is for removing the glass substrate 60 effectively.

Next, in case of a transmissive display element, a film-shape base layer 40 constituted of a transparent resin film is formed on the sacrificial film 61 in the thickness of about 5 μm, for example. As the resin material to form the base layer 40, a polyimide resin, a fluorene-type epoxy resin, or a fluorine resin can be used. The base layer 40 is formed by applying a resin onto the surface of the sacrificial film 61. In case of a reflective display element, or in case of a top emission self-light emitting display element, a sacrificial film may be omitted by forming the base layer 40 using the same resin material as the resin material used to form the sacrificial film 61.

Thereafter, as shown in FIG. 9, on the base layer 40, second TFT elements 41 which are active elements for a driver circuit (that is, the gate driver 23), and which have a higher mobility than the mobility of the first TFT element 4 are formed by forming a metal film, a semiconductor film, and the like, and performing patterning and the like.

Next, on the base layer 40 having the second TFT elements 41 formed thereon, an interlayer insulating film 42 is formed in the thickness of about 1 to 2 μm, using an SiO₂ film, an SiN film, or the like, for example.

Then, contact holes running from the surface of the interlayer insulating film 42 to the second TFT elements 41 are formed, and metal wiring lines 43 electrically connected to the second TFT elements 4 are formed by a transparent conductive material such as ITO or the like.

After that, as shown in FIG. 10, the glass substrate 60 is removed by radiating laser light (the arrows in FIG. 10) from the glass substrate 60 side.

Here, the laser light irradiation need not be used in removing the glass substrate 60. The glass substrate 60 may be removed by using polishing and an etching device, for example.

Next, as shown in FIG. 11, the sacrificial film 61 exposed by the removal of the glass substrate 60 is removed by plasma etching. Here, the removal method of the sacrificial film 61 is not limited to plasma etching, and it may be done by microwave plasma etching, for example. In case of a reflective display element, or a top emission self-light emitting display element, there is no need to perform etching for the sacrificial film 61.

Next, as shown in FIG. 12, an unnecessary portion in which the second TFT elements 41 are not formed is removed by cutting.

In a manner described above, the driver circuit substrate 27 is fabricated.

(Substrate Bonding Step)

First, as shown in FIG. 13, in the driver circuit region 21 of the display substrate 26, a film-shape anisotropic conductive film mainly made of a thermosetting resin, such as an epoxy resin, for example, is placed as the conductive member 28, and a prescribed pressure is applied in the direction to the display substrate 26 to connect the anisotropic conductive film and the metal wiring line 6 in the driver circuit region 21, thereby temporarily bonding the anisotropic conductive film to the display substrate 26.

Next, as shown in FIG. 14, placing the prepared driver circuit substrate 27 in a downward direction (facing down), and having the anisotropic conductive film between the display substrate 26 and the driver circuit substrate 27, the display substrate 26 and the driver circuit substrate 27 are positioned so that the metal wiring line 6 formed in the display substrate 26 will be connected to the metal wiring lines 43 formed in the driver circuit substrate 27.

Next, as shown in FIG. 15, the metal wiring lines 43 formed in the driver circuit substrate 27 are placed on the anisotropic conductive film. Then, with the anisotropic conductive film heated at a prescribed curing temperature, a prescribed pressure is applied to the anisotropic conductive film through the driver circuit substrate 27 in the direction toward the display substrate 26 so as to melt the anisotropic conductive film by heat. As described above, the anisotropic conductive film is mainly made of a thermosetting resin. Therefore, when heated at the prescribed curing temperature, the film softens first, and then hardens as the heating continues. When the prescribed curing time of the anisotropic conductive film has passed, the heating at the curing temperature of the anisotropic conductive film is stopped, and the cooling is started. This connects the metal wiring line 6 and the metal wiring lines 43 through the anisotropic conductive film. As a result, in the driver circuit region 21, the display substrate 26 and the driver circuit substrate 27 are bonded together via the adhesive conductive member 28, and the first TFT element 4 and the second TFT elements 41 are electrically connected through the conductive member 28 and the metal wiring lines 6 and 43. Thus, the electrical conduction between the first TFT element 4 and the second TFT elements 41 is established.

After that, as shown in FIG. 16, the glass substrate 50 is removed by radiating laser light (the arrows in FIG. 16) from the glass substrate 50 side.

Here, the removal method of glass substrate 50 is not limited to removal by the laser light irradiation. The glass substrate 50 may be removed by using polishing and an etching device, for example.

Next, as shown in FIG. 17, the sacrificial film 51 exposed by the removal of the glass substrate 50 is removed by plasma etching. Here, the removal method of the sacrificial film 51 is not limited to plasma etching, and it may be done by microwave plasma etching, for example. In case of a reflective display element, or a top emission self-light emitting display element, there is no need to perform etching of the sacrificial film 51.

In a manner described above, the organic EL display device 1 according to this embodiment can be manufactured.

According to this embodiment described above, the following effects can be obtained.

(1) In this embodiment, a configuration of fabricating the display substrate 26 by forming the first TFT elements 4 and the organic EL display element 11 on the film-shape base layer 2 is adopted. Also, a configuration of fabricating the driver circuit substrate 27 by forming, on the film-shape base layer 40, the second TFT elements 41 having a higher mobility than the mobility of the first TFT element 4 is adopted. Further, in this embodiment, a configuration of bonding the display substrate 26 and the driver circuit substrate 27 via the adhesive conductive member 28, and electrically connecting the first TFT element 4 and the second TFT elements 41 in the driver circuit region 21 is adopted. Therefore, because of the configuration of bonding the film-shape display substrate 26 and the film-shape driver circuit substrate 21, the entire organic EL display device 1 can be formed of films. As a result, the organic EL display device 1 with a superior flexibility can be provided.

(2) Also, because of the configuration of bonding the display substrate 26 and the driver circuit substrate 27 via the conductive member 28, the yield of the organic EL display device 1 can be improved as compared with a case of transferring TFT elements to a transfer body.

(3) Further, the mobility of the first TFT element 4 formed in the display substrate 26 is smaller than the mobility of the second TFT element 41 formed in the driver circuit substrate 27. Therefore, the organic EL display device 1 having a large screen (that is, a large display region 22) can be provided.

(4) Also, the mobility of the second TFT element 41 formed in the driver circuit substrate 27 is higher than the mobility of the first TFT element 4. Therefore, the organic EL display device 1 having a driver circuit capable of rapid response can be provided.

(5) In this embodiment, a configuration of using a conductive adhesive as the conductive member 28 is adopted. Therefore, the electrical conduction between the first TFT element 4 and the second TFT element 41 can be established reliably with ease when the display substrate 26 and the driver circuit substrate 27 are bonded together.

(6) In this embodiment, a configuration of using a conductive paste as the conductive member 28 is adopted. Therefore, the electrical conduction between the first TFT element 4 and the second TFT element 41 can be established reliably with ease when the display substrate 26 and the driver circuit substrate 27 are bonded together.

(7) In this embodiment, a configuration of forming the base layer 2 and the base layer 40 of the same material is adopted. Therefore, the thermal expansion coefficients of the base layer 2 and the base layer 40 can be set to the same value, and the distortion in bonding the display substrate 26 and the driver circuit substrate 27 can be thereby reduced.

(8) In this embodiment, a configuration of using amorphous silicon as a channel of the first TFT element 4, and using polysilicon as a channel of the second TFT element 41 is adopted. This makes it possible to use generally available materials to form the first TFT element 4 that can provide a large screen and to form the second TFT element 41 capable of rapid response.

The above embodiment can be modified as follows.

After bonding the display substrate 26 and the driver circuit substrate 27 via the conductive member 28 and electrically connecting the first TFT element 4 and the second TFT element 14 in the driver circuit region 21 as shown in FIG. 18, a laminate layer 45 may be provided to cover the bonded body obtained by bonding the display substrate 26 and the driver circuit substrate 27. With such a configuration, damage to the organic EL display device 1 caused by dust, dirt, and the like can be effectively prevented. As a material to form the laminate layer 45, a polyparaxylene resin, an epoxy resin, an acrylic resin, or the like can be used, for example. However, from a perspective of providing insulation protection to the organic EL display device 1, it is preferable to use a polyparaxylene resin. For a method of forming the laminate layer 45, a method of coating the surfaces of the display substrate 26 and the driver circuit substrate 27 with a polyparaxylene resin by CVD, or a method of coating the surfaces by applying an epoxy resin or an acrylic resin can be adopted, for example. Also, the thickness of the laminate layer 45 can be set to 20 μm, for example.

Also, as shown in FIG. 19, forming a contact hole 46 in the base layer 40 and the interlayer insulating film 42 of the driver circuit substrate 27, and disposing a different conductive member 47 in the contact hole 46 to connect the metal wiring line 6 and the metal wiring line 43 through the different conductive member 47 and the above-mentioned anisotropic conductive film (that is, the conductive member 28) is another possible configuration.

Although the gate driver 23 was constituted by the driver circuit substrate 27 in the embodiment above, a source driver 24 may also be constituted by the driver circuit substrate 27. Similar to the driver circuit substrate 27 constituting the gate driver 23, the driver circuit substrate 27 constituting the source driver 24 may be configured to be bonded together with the display substrate 26 via the conductive member 28 in the driver circuit region 21. In such a configuration, the source driver 24 is also constituted by the film-shape driver circuit substrate 27 having a superior flexibility, and therefore, the organic EL display device 1 having even higher flexibility can be provided.

Also, although a TFT using amorphous silicon was used for the first TFT element 4 in the embodiment above, a TFT having an organic semiconductor as a channel thereof, or a TFT having a carbon nanotube as a channel thereof may also be used for the first TFT element 4 as another possible configuration. In such a configuration, similar to when a TFT including amorphous silicon is used as the first TFT element 4, the first TFT element 4 that can provide a large screen can be formed of generally available materials.

Although an organic EL (organic electro luminescence) display device has been exemplified as the display device in the embodiment above, the display device may also be a display device of other types, such as LCD (liquid crystal display), electrophoretic, PD (plasma display), PALC (plasma addressed liquid crystal display), inorganic EL (inorganic electro luminescence), FED (field emission display), and SED (surface-conduction electron-emitter display).

### INDUSTRIAL APPLICABILITY

As explained above, the present invention is useful for a method of manufacturing a display device and for a display device manufactured by the method thereof.

### DESCRIPTION OF REFERENCE CHARACTERS

1 organic EL display device

2 base layer (first substrate)

4 first TFT element

11 organic EL display element

20 pixel

21 driver circuit region

22 display region

23 gate driver (driver circuit)

24 source driver (driver circuit)

26 display substrate

27 driver circuit substrate

28 conductive member

40 base layer (second substrate)

41 second TFT element

1. A method of manufacturing a display device including a display region having pixels, and a driver circuit region disposed around said display region, the method comprising at least:
a first step of fabricating a film-shape display substrate by forming a first TFT element that is a switching element of the pixel and a display element on a first substrate;
a second step of fabricating a film-shape driver circuit substrate by forming, on a second substrate, a second TFT element that is an active element of a driver circuit and that has a higher mobility than a mobility of the first TFT element; and
a third step of bonding the display substrate and the driver circuit substrate via an adhesive conductive member to electrically connect the first TFT element and the second TFT element in a driver circuit region.

2. The method of manufacturing a display device according to claim 1, wherein the conductive member is a conductive adhesive.

3. The method of manufacturing a display device according to claim 1, wherein the conductive member is a conductive paste.

4. The method of manufacturing a display device according to claim 1, wherein the first substrate and the second substrate are formed of a same material.

5. The method of manufacturing a display device according to claim 1, further comprising a step of coating, with a laminate layer, a bonded body obtained by bonding the display substrate and the driver circuit substrate after the above-mentioned third step.

6. The method of manufacturing a display device according to claim 5, wherein the laminate layer is formed of a polyparaxylene resin.

7. The method of manufacturing a display device according to claim 1, wherein the first TFT element uses one material selected from a group constituted of amorphous silicon, an organic semiconductor, and a carbon nanotube as a channel thereof, and the second TFT element uses polysilicon as a channel thereof.

8. The method of manufacturing a display device according to claim 1, wherein the display element is an organic EL display element.

9. A display device manufactured by the manufacturing method according to claim 1.
